(19) United States
(12) Patent Application Publication
(10) Pub. No.: US 2025/0284274 A1
(43) Pub. Date: Sep. 11, 2025

(54) REAL TIME IN-SITU METROLOGY AND PROCESS PERFORMANCE IMPROVEMENT

(71) Applicant: Applied Materials, Inc., Santa Clara, CA (US)

(72) Inventors: ROMAN MOSTOVOY, San Francisco, CA (US); JINGMIN LENG, Fremont, CA (US); ARUN SRIVATSA, Santa Clara, CA (US)

(21) Appl. No.: 18/600,422

(22) Filed: Mar. 8, 2024

(51) Int. Cl. G05B 23/02; H01L 21/66

(52) U.S. Cl. CPC G05B 23/0283; H01L 22/12; H01L 22/20; G05B 2219/45031

(57) ABSTRACT

Embodiments disclosed herein include a method for maintaining a processing tool. In an embodiment, the method comprises performing a planned maintenance (PM) process on the processing tool. The method may continue with processing substrates on the processing tool, and performing an in-situ metrology and cleaning process on the processing tool with an optimization substrate. The process may be used to determine if a processing parameter of the processing tool is within a specified range. In an embodiment, the method may continue with restarting substrate processing on the processing tool when the processing parameter is within the specified range.

### BACKGROUND

### 1) Field

Embodiments relate to the field of semiconductor and/or flat panel manufacturing, in particular, to real time in-situ metrology for process improvement for semiconductor and panel fabrication processes.

### 2) Description of Related Art

In semiconductor manufacturing processes, smaller and more densely packed feature sizes are necessary as the size and complexity of integrated circuit structures continue to scale to smaller dimensions. In order to fabricate such features, precision and repeatability of manufacturing processes are driven to their extremes. In order to meet these requirements, the manufacturing tools, associated metrology tools, and the chambers connecting systems together need to be operating at near perfect conditions. This results in strict processing parameters that need to be met in order to continue high volume manufacturing (HVM) on a given tool.

In order to satisfy these demands, frequent maintenance is often required. Chamber cleaning recipes are a first option to bring a tool back into compliance with the strict processing parameters. However, when a chamber clean recipe is not sufficient, a planned maintenance (PM) process is implemented. PM processes may also be scheduled at standard intervals (e.g., time based or after a predetermined number of substrates have been processed).

However, PM processes are exceedingly time intensive. For example, the tool needs to be cooled, the vacuum needs to be released, and the chamber is opened. An extensive cleaning of the interior of the chamber is then completed. After the clean, the chamber will undergo a seasoning process and a qualification process is implemented to ensure the chamber is back within certain specifications. Overall, the PM process may take multiple days to complete. This significantly increases the cost of ownership of the tool, and results in a significant throughput decrease in the fabrication facility (fab).

### SUMMARY

Embodiments disclosed herein include a method for maintaining a processing tool. In an embodiment, the method includes performing a planned maintenance (PM) process on the processing tool. The method may continue with processing substrates on the processing tool, and performing an in-situ metrology and cleaning process on the processing tool with an optimization substrate. The process may be used to determine if a processing parameter of the processing tool is within a specified range. In an embodiment, the method may continue with restarting substrate processing on the processing tool when the processing parameter is within the specified range.

Embodiments disclosed herein may also include an apparatus for providing in-situ metrology and chamber cleaning. In an embodiment, the apparatus includes a substrate with a first surface and a second surface opposite from the first surface. In an embodiment, a layer is on the second surface of the substrate, and the layer is configured to attract particles from an environment surrounding the apparatus. In an embodiment, a plurality of sensors are on the substrate, and the plurality of sensors are configured to detect particles landing on the apparatus. In an embodiment, the apparatus may further include a controller on the substrate that is communicatively coupled to the plurality of sensors. In an embodiment, the controller includes a processor, a memory, and a power source.

Embodiments may also include a method for maintaining a processing tool that includes performing a planned maintenance (PM) process on the processing tool, and processing substrates on the processing tool. In an embodiment, the method may further include performing an in-situ metrology and cleaning process on the processing tool with an optimization substrate to determine if a processing parameter of the processing tool is within a specified range. In an embodiment, the in-situ metrology and cleaning process includes providing the optimization substrate to the processing tool. In an embodiment, the optimization substrate includes a substrate, a layer over the substrate, that is configured to attract particles in the processing tool, and a sensor on the substrate that is configured to detect the processing parameter. In an embodiment, the method may further include processing the optimization substrate with an optimization recipe a plurality of cycles until the processing parameter is within the specified range. In an embodiment, the method may further include restarting substrate processing on the processing tool when the processing parameter is within the specified range.

### BRIEF DESCRIPTION OF THE DRAWINGS

FIG. 1 is a process flow diagram of a process for initiating a planned maintenance (PM) process on a tool and bringing the tool back online after the planned maintenance.

FIG. 2 is a process flow diagram of a process for initiating a PM process on a tool and bringing the tool back online with the use of an optimization substrate that executes both in-situ metrology and a cleaning process, in accordance with an embodiment.

FIG. 3 is a graph comparing the high volume manufacturing (HVM) life-cycle of a tool that uses a traditional maintenance process with a tool that uses an optimization substrate that executes both in-situ metrology and a cleaning process, in accordance with an embodiment.

FIG. 4 is a graph of the performance over time of a first tool with a traditional maintenance process and a second tool with a maintenance process that is improved through the use of an optimization substrate that executes both in-situ metrology and a cleaning process, in accordance with an embodiment.

FIG. 5A is a cross-sectional illustration of an optimization substrate with a layer for collecting particles, in accordance with an embodiment.

FIG. 5B is a cross-sectional illustration of an optimization substrate with a first layer over the substrate and a second layer under the substrate, where both the first layer and the second layer are configured to collect particles, in accordance with an embodiment.

FIG. 5C is a cross-sectional illustration of an optimization substrate with a patterned layer for collecting particles, in accordance with an embodiment.

FIG. 6A is a plan view illustration of an optimization substrate with a layer for collecting particles and a plurality of sensors, in accordance with an embodiment.

FIG. 6B is a cross-sectional illustration of an optimization substrate with a layer for collecting particles, a plurality of sensors, and a controller that is communicatively coupled to the plurality of sensors, in accordance with an embodiment.

FIG. 7 is a plan view illustration of a cluster tool that can have an optimized maintenance schedule through the use of optimization substrates that execute both in-situ metrology and a cleaning process, in accordance with an embodiment.

FIG. 8 is a cross-sectional illustration of a chamber in a tool that can have an optimized maintenance schedule through the use of an optimization substrate that executes both in-situ metrology and a cleaning process, in accordance with an embodiment.

FIG. 9 illustrates a block diagram of an exemplary computer system that may be used in conjunction with a processing tool, in accordance with an embodiment.

### DETAILED DESCRIPTION

Embodiments described herein include apparatuses and methods for real time in-situ metrology for process improvement for semiconductor and panel fabrication processes. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, planned maintenance (PM) operations are necessary on semiconductor processing tools in order to meet the exceedingly precise processing parameters needed to fabricate modern integrate circuitry and the like. However, the PM processes as they exist today are implemented at intervals that make cost of ownership of the tool high. Repeated PM processes also decrease throughput in the fabrication facility (fab). The frequency of the PM processes is driven (at least in part) by the constant drift of the processing parameters once the tool has been qualified. Typically, this drift tends to bring the tool out of control (OoC) (also referred to as being out of specification, or out of compliance) over time.

One particular parameter that can lead to defects is particle generation. When particles land on portions of circuitry, the particle can completely ruin (i.e., render defective) a device. This can lead to significant yield reductions. As such, when particle concentrations within a tool get too high, the tool is considered OoC. Particles can be generated by many different sources. For example, friction between a substrate and one or more of a pedestal, a robot, a cover ring, etc., may result in the generation of particles. Particles may also be introduced into the tool from carry on gasses and/or precursor gasses. Plasma and/or chemical reactions may also generate particles. Accordingly, as more substrates are processed the particle concentration will generally increase.

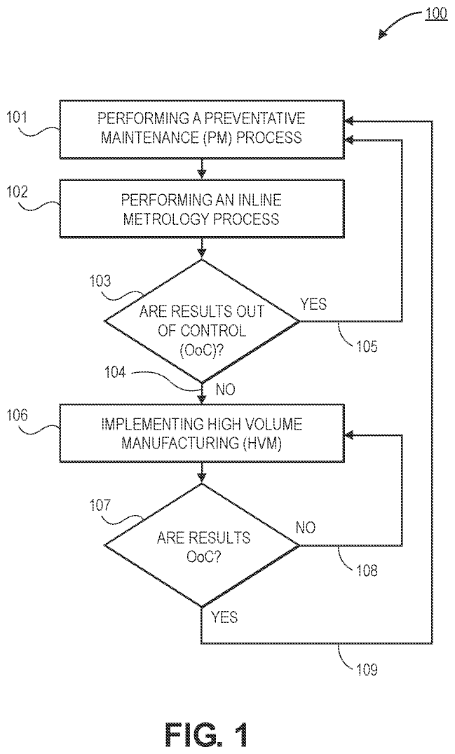

Referring now to FIG. 1, a process 100 for performing a PM process, qualifying the tool, and operating the tool in an high volume manufacturing (HVM) condition is shown using typical processes. As shown, the process 100 may include operation 101, which comprises performing a PM process on the tool. The PM process may include cooling the tool, releasing a vacuum within a chamber, and opening the chamber. An extensive cleaning of the interior of the chamber is then completed. After the clean, the chamber will undergo a seasoning process.

The seasoning process may include running one or more qualifying substrates to determine if the tool is meeting specifications. The qualifying substrates are non-production substrates that are used for the sole purpose of verifying the performance of the tool. The number of qualifying substrates that are run may be as few as one or as many as twenty or more. All qualifying substrates may undergo the same process recipe. Alternatively, qualifying substrates may undergo two or more different process recipes in order to quantify different process regimes.

After operation 101, the process 100 may continue with operation 102, which comprises performing an inline metrology process. The inline metrology may be performed on one or more of the qualifying substrates. The inline metrology process may be referred to as a non in-situ metrology process. That is, the metrology is performed outside of the processing chamber. The inline metrology process may include a defect detection process. For example, an incident laser beam directed at the substrate may be used to detect imperfections on the substrate surface. That is, a defect may be detected when the laser beam is scattered.

Following operation 102, the process 100 may continue to decision block 103 where it is determined if the results of the inline metrology indicate that the tool is OoC. If the YES branch 105 is taken (i.e., the tool is OoC), then the process 100 loops back to operation 101, and another PM process is performed. This is a significant event since PM processes are long and expensive events. However, under typical process flows, the chance of requiring a second PM process is not insignificant. This is due (at least in part) to the PM process being largely a manual process and is susceptible to human error. Furthermore, another set of qualifying substrates are processed and additional inline metrology (operation 102) is needed when branch 105 is taken.

After the tool is qualified (i.e., the NO branch 104 is taken), the tool is brought online and operation 106 is started, which comprises implementing HVM production. During HVM production, production substrates may be chosen for further inline metrology at predetermined intervals (e.g., based on time or based on number of substrates processed). At each instance of inline metrology, decision block 107 is implemented to determine if the results indicate the tool is OoC. In the desirable case, the NO branch 108 is taken, and the process 100 loops back to operation 106, where HVM production is continued. However, if the YES branch 109 is taken, the process 100 loops back to operation 101, and an additional PM process is started.

It is to be appreciated that once operation 106 is initiated (i.e., HVM production), some in-situ chamber clean recipes may be implemented, but otherwise, the tool is left to drift towards being OoC. Depending on the particular tool, this may lead to a relatively short period of HVM production (e.g., several days to a week). When viewed in light of the extensive requalification process that may include one or more PM processes, this limited uptime can lead to high cost of ownership of the tool and decreased throughput in the fab.

Accordingly, embodiments disclosed herein include the use of an optimization substrate. The optimization substrate may include the functionality to provide in-situ metrology while also cleaning the tool at the same time. For example, in the case of the monitoring and control of particle generation, the optimization substrate may include a layer configured to attract and trap particles in order to reduce the particle concentration in the tool. The optimization substrate may also include one or more sensors for measuring the particle concentration within the tool.

Such an optimization substrate can benefit a tool in several ways. One benefit is in the qualification process. By running an optimization substrate through the tool one or more times before qualification, the inline metrology is more likely to yield passing results. This can result in the ability to move to HVM production without additional PM processes. Additionally, during the HVM production, optimization substrates can be cycled at certain intervals to monitor the targeted process parameter (e.g., particle concentration) while also improving the process parameter (e.g., removing particles from the tool). This can lengthen the uptime of the tool, which reduces cost of ownership and improves throughput in the fab.

While particle generation is one issue that can render a tool OoC, other processing parameters may also result in non-optimal tool conditions. For example, plasma non-uniformity (e.g., with respect to density, composition, etc.), UV uniformity, excessive vibrations, temperature uniformity (e.g., uneven heat flux), gas flow uniformity, chamber calibration (e.g., chamber matching between chambers), and the like can all lead to a tool being OoC.

In the embodiments described herein, particular explanation is given to the issue of particle generation, but it is to be appreciated that many different processing parameters may be addressed with embodiments disclosed herein. For example, when an optimization substrate is described with sensors, the sensors may include sensors suitable for detecting any of the processing parameter conditions (or sensors for detecting conditions related to those processing parameter conditions).

Additionally, multiple different sensor types can be provided on a single optimization substrate. For example, particle detection sensors and temperature sensors may both be provided on the optimization substrate. This allows for the detection of both particle concentration excursions and temperature excursions with a single optimization substrate.

In some embodiments, the process parameter sensor may also be paired with a position sensor. For example, particle detection sensors may be paired with one or more accelerometers on a single optimization substrate. This may allow for position tracking of the optimization substrate so that the location of the optimization substrate is known when particles are detected. This can be used to find regions or locations within the tool where high levels of particles are located. Further cleaning (e.g., by allowing the optimization substrate to reside in those locations for longer durations) may then be implemented to prolong the uptime of the tool. When a PM is ultimately needed, the identified locations of high particle concentration can be given special attention during the cleaning process.

In an embodiment, any type of tool may benefit from the use of an optimization substrate such as those described herein. For example, tools such as, but not limited to, physical vapor deposition (PVD) tools, atomic layer deposition (ALD) tools, chemical vapor deposition (CVD) tools, plasma enhanced ALD or CVD tools, etching tools, front end packaging (FEP) tools, electrochemical plating (ECP) tools, ion implantation tools, or the like may be used in accordance with embodiments described herein. Metrology tools (e.g., laser particle detection tools, scanning electron microscopy (SEM) tools, critical dimension SEM (CD-SEM) tools, bright and dark optical inspection tool, or the like) may also benefit from optimization substrates. In an embodiment, the tool may also comprise a cluster tool with one or more different types of chambers. The optimization tool may provide validation and cleaning to any of the chambers, transfer chambers, load locks, equipment front end modules (EFEMs), or the like.

In an embodiment, the optimization substrate may take any suitable form factor. For example, the optimization substrate may have a wafer-like form factor. That is, the optimization substrate may be roughly circular with a diameter of 300 mm, 450 mm, or the like. A thickness of the optimization substrate may allow for transport within the tool under investigation using existing wafer handling robots and/or the like. In other embodiments, the optimization substrate may have a panel form factor, a half-panel form factor, a quarter-panel form factor, or the like. That is, embodiments may include wafer based tools for integrated circuit processing or panel based tools for electronics packaging, display technologies, and/or the like.

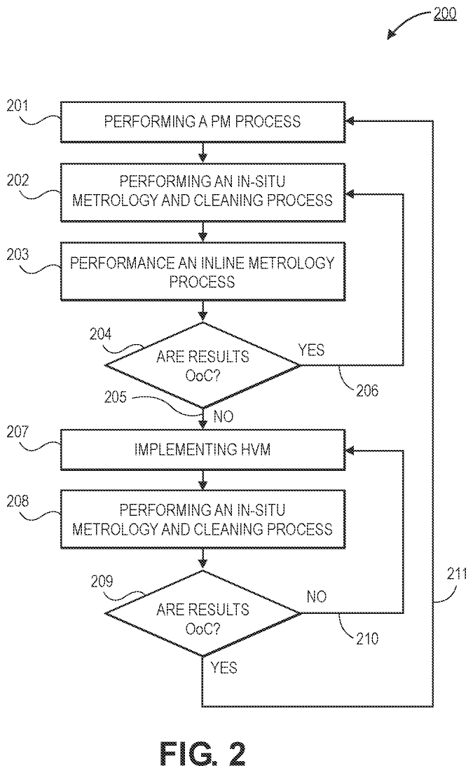

Referring now to FIG. 2, a process 200 for performing a PM process, qualifying the tool, and operating the tool in an HVM condition is shown, in accordance with an embodiment. In an embodiment, the process 200 may include operation 201, which comprises performing a PM process on the tool. The PM process may include cooling the tool, releasing a vacuum within a chamber, and opening the chamber. An extensive cleaning of the interior of the chamber is then completed. After the clean, the chamber may undergo a seasoning process.

In an embodiment, the tool may comprise any type of tool, such as those described in greater detail herein. For example, the tool may include a deposition tool, an etching tool, an ion implantation tool, or a metrology tool. The tool may also be a cluster tool that comprises one or more different types of chambers that are coupled together with transfer chambers, load locks, EFEMs, and/or the like. The process 200 may be used in order to qualify and/or maintain a single chamber within a cluster tool, multiple different chambers within a cluster tool, and/or the entire cluster tool.

In an embodiment, the process 200 may then continue with operation 202, which comprises performing an in-situ metrology and cleaning process. In an embodiment, the in-situ metrology and cleaning process may be implemented by providing an optimization substrate into the tool. The optimization substrate may include one or more sensors for detecting and/or determining a process parameter (e.g., particle concentration, thermal properties, plasma properties, vibration, etc.), and a surface for cleaning the tool (e.g., a surface configured to trap particles). In an embodiment, the optimization substrate may be treated before being sent into the tool. For example, the optimization substrate may be charged (with a positive charge or a negative charge) and/or heated. Providing a charge and/or heating the optimization substrate may improve the efficiency of particle capture in some embodiments.

In an embodiment, operation 202 may include running the optimization substrate through the tool while implementing an optimization recipe. The optimization recipe may include setting one or more of gas flow rates, duration within the tool, positioning within the tool, temperature cycles, plasma cycles, lift pin cycles, and/or the like to certain values in order to aid in the collection of data and/or to improve particle collection. Operation 202 may include running the optimization substrate through the tool with the optimization recipe a single time, or multiple cycles may be implemented.

As opposed to going directly to the qualification process, as described in process 100 above, the inclusion of operation 202 allows for the tool to be cleaned further and for initial metrology measurements to be taken. Particularly, the use of in-situ metrology measurement (i.e., metrology measurements within the chamber during operation) allow for quicker analysis of the cleanliness of the tool. The optimization substrate can be cycled through the tool any number of times in operation 202 in order to improve the probability of passing the qualification process. For example, operation 202 may be repeated until the in-situ metrology reports an acceptable level for particle concentration. Furthermore, each cycle will reduce the particle concentration due to the cleaning effects of the optimization substrate.

After operation 202 is completed, qualifying substrates may be run through the tool with a process similar to the use of qualifying substrates described above. The qualifying substrates may then be used in operation 203, which comprises performing an inline metrology process. Following operation 203, the process 200 may continue to decision block 204 where it is determined if the results of the inline metrology indicate that the tool is OoC. If the YES branch 206 is take (i.e., the tool is OoC), then the process 200 loops back to operation 202, and one or more cycles of in-situ metrology and cleaning is implemented.

After the tool is qualified (i.e., the NO branch 205 is taken), the tool is brought online and operation 207 is started, which comprises implementing HVM production. In an embodiment, the path to get to operation 207 is improved compared to the process 100 described in greater detail above. This is because the probability of needing additional PM processes is significantly reduced. This is for several reasons. First, the in-situ metrology and cleaning process enhances the performance of the tool, and allows for moving on to the qualifying process only after certain metrics are hit (e.g., particle concentration thresholds). This makes it more likely that the tool is within specification after the first qualifying process. Additionally, even if the qualifying process fails, additional cycles of the in-situ metrology and cleaning process can be implemented to help move the tool towards qualification. However, if multiple failures occur at decision block 204, the process may proceed back and implement another PM process. Though, this will be rare, and fewer PM processes will be needed during the life of the tool compared to the use of process 100.

In an embodiment, process 200 may continue with operation 208, which comprises performing an in-situ metrology and cleaning process. In an embodiment, the in-situ metrology and cleaning process may be implemented by providing an optimization substrate into the tool. The optimization substrate may include one or more sensors for detecting and/or determining a process parameter (e.g., particle concentration, thermal properties, plasma properties, vibration, etc.), and a surface for cleaning the tool (e.g., a surface configured to trap particles). In an embodiment, the optimization substrate may be treated before being sent into the tool (e.g., charged and/or heated). Multiple cycles of the in-situ metrology and cleaning process may also be used in some embodiments. More generally, operation 208 may be similar to operation 202 in some embodiments.

In an embodiment, operation 208 may be implemented after any suitable duration after the beginning of operation 207. In some embodiments, operation 208 may occur after a certain number of substrates have been processed (e.g., 50 substrates or more, 100 substrates or more, 500 substrates or more). In other embodiments, operation 208 may occur after a suitable period of time (e.g., after 12 hours, after 24 hours, after 48 hours, etc.). The timing of operation 208 may also be chosen to coincide with a time period when the tool is otherwise idling. In such instances, useful production time is not used by the inline metrology and cleaning process.

In an embodiment, operation 208 provides a couple benefits. First, the in-situ metrology component allows for monitoring a parameter of the chamber (e.g., particle concentration). This allows for a picture of tool health to be obtained in order to help determine when the next PM process is necessary. Second, the cleaning component improves the longevity of the HVM duration. For example, removing particles from the tool allows for the tool to remain within specification for a longer duration. This provides a longer time period between PM events, which reduces cost of ownership and improves fab throughput.

In an embodiment, process 200 may continue to decision block 209 after operation 208. At decision block 209, it is determined if the tool is OoC. This decision can be based (at least in part) on the results of the in-situ metrology from operation 208. If the tool is not OoC, the NO branch 210 is taken, and the process 200 returns to operation 207 so that HVM production can continue. If the tool is OoC, the YES branch 211 is taken. This may result in the process 200 returning back to operation 201, where a new PM process is started. In some embodiments, if the YES branch 211 is taken, an inline metrology analysis may be implemented to confirm the finding before returning to operation 201.

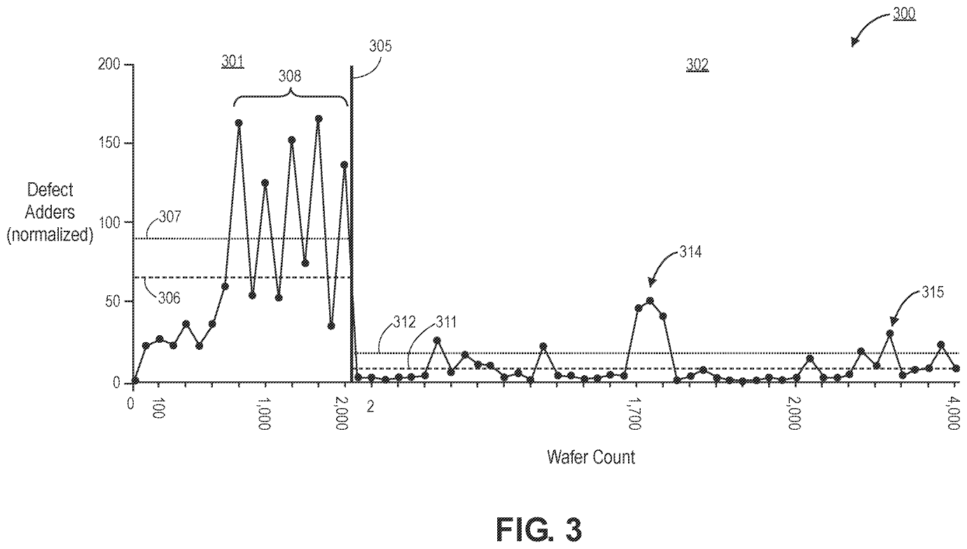

Referring now to FIG. 3, a graph 300 illustrating a count of defect adders over the course of processing substrates is shown, in accordance with an embodiment. The first section 301 of the graph to the left of line 305 illustrates a tool that uses a process similar to process 100 described in greater detail above. As shown, the defect count becomes unstable in region 308 with defect counts greatly exceeding the warning bands 306 to 307 that set the OoC specification of the tool. As such, a PM process is quickly needed.

In contrast the second section 302 to the right of the line 305 illustrates a tool that uses a process similar to process 200 described in greater detail above. As shown, the warning bands 311 and 312 can be set lower, and the consistency of the operation is improved. As shown, when high defect adder counts are detected (e.g., at location 314 and location 315), one or more cycles using an optimization substrate can be run in order to monitor (with in-situ metrology) and clean the tool. As such, the duration of HVM operation can be extended. For example, FIG. 3 shows up to 4,000 substrates being processed (which is twice as many as in the first section 301), and the tool is still within specification in order to continue with HVM processes.

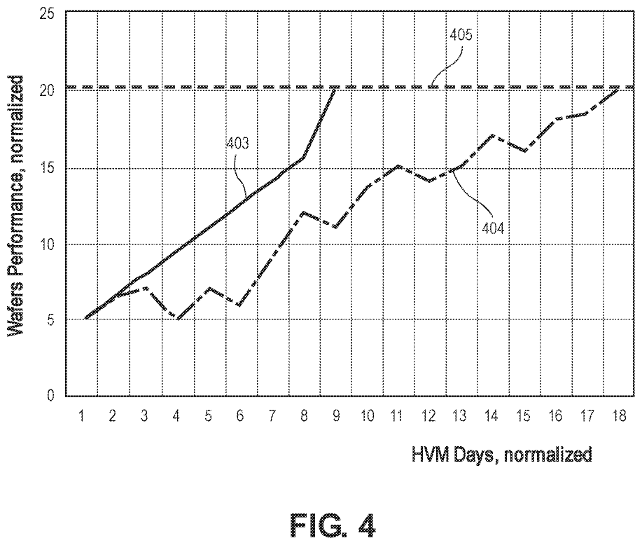

Referring now to FIG. 4, a graph showing wafer performance over the course of HVM days (i.e., days during which HVM processing is implemented) is shown, in accordance with an embodiment. As shown, the threshold 405 for being OoC or out of specification is around 20. Once the performance exceeds this predetermined level, the tool will need a PM process in order to bring the tool back into compliance with the specification.

As shown, the line 403 showing a tool operating under process 100 is continuously increasing. This corresponds to the tool drifting towards being out of specification during the entire HVM run. In contrast, the line 404 showing a tool operating under process 200 includes increasing and decreasing portions. The decreasing portions correspond to use of an optimization substrate (either a single cycle or multiple cycles). Accordingly, by improving the wafer performance at regular intervals, the HVM duration can be increased. For example, the HVM duration of line 403 is 8.75 days, and the HVM duration of line 404 is approximately 17.75 days (which is over double the duration of line 403). Accordingly, the use of process 200 can significantly increase tool uptime, which reduces cost of ownership and increases throughput in the fab.

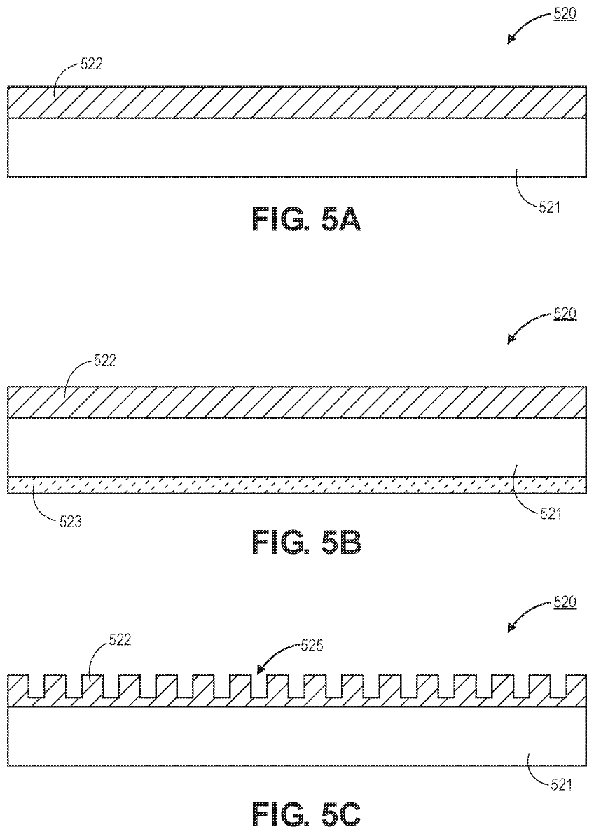

Referring now to FIGS. 5A-5C, a series of cross-sectional illustrations depicting portions of an optimization substrate 520 is shown, in accordance with various embodiments.

Referring now to FIG. 5A, a cross-sectional illustration of the optimization substrate 520 is shown, in accordance with an embodiment. In an embodiment, the optimization substrate 520 may comprise a substrate 521. The substrate 521 may have a first surface (i.e., bottom surface) and a second surface (i.e., top surface). In an embodiment, a layer 522 is provided over the second surface. In an embodiment, the layer 522 may be a blanketed layer. That is, the layer 522 may cover substantially all of the second surface of the substrate 521. Though, in other embodiments, the layer 522 may cover a portion of the second surface of the substrate 521.

In an embodiment, the layer 522 may be a material (or materials) that is configured to attract and/or retain particles from a tool environment. The attraction of particles to the layer 522 may be improved by providing a charge (e.g., positive or negative) to the optimization substrate 520 and/or by heating the optimization substrate 520 before being provided to the tool. In other embodiments, a surface roughness of the layer 522 may be relatively high in order to provide a greater surface area for attracting and retaining particles.

In an embodiment, the optimization substrate 520 may have a wafer-like form factor. That is, the optimization substrate may be roughly circular with a diameter of 300 mm, 450 mm, or the like. A thickness of the optimization substrate (e.g., including the substrate 521 and the layer 522) may allow for transport within the tool under investigation using existing wafer handling robots and/or the like. For example, a total thickness of the optimization substrate 520 may be approximately 5 mm or less, approximately 3 mm or less, or approximately 1 mm or less. In other embodiments, the optimization substrate 520 may have a panel form factor, a half-panel form factor, a quarter-panel form factor, or the like. That is, embodiments may include wafer based tools for integrated circuit processing or panel based tools for electronics packaging, display technologies, and/or the like.

In an embodiment, the substrate 521 may comprise any material suitable for transport within a tool. For example, the substrate 521 may have a modulus and/or rigidity that enables transferring the optimization substrate 520 with substrate handling robots within the tool. For example, the substrate 521 may comprise silicon, silicon carbide, graphite, aluminum, a ceramic, or any other suitable dielectric or conductive materials. In an embodiment, the layer 522 may comprise one or more of silicon nitride, silicon oxide, alumina, aluminum, titanium, a polymer, or a sol-gel (e.g., a silicon oxide sol-gel, an alumina sol-gel, or the like).

Referring now to FIG. 5B, a cross-sectional illustration of an optimization substrate 520 is shown, in accordance with an additional embodiment. The optimization substrate 520 in FIG. 5B may be similar to the optimization substrate 520 in FIG. 5A, with the addition of a second layer 523 on the first surface (i.e., bottom surface) of the substrate 521. In an embodiment, the second layer 523 may comprise the same material (or materials) as the layer 522. In other embodiments, the second layer 523 may comprise a different material than the layer 522. Material options for the second layer 523 may be similar to those listed above for use in the layer 522. Additionally, a thickness of the second layer 523 may be substantially equal to a thickness of the layer 522, or a thickness of the second layer 523 may be different than a thickness of the layer 522. The second layer 523 may be a blanket layer across the entire first surface, or the second layer 523 may cover a portion of the first surface.

In an embodiment, providing a second layer 523 on the optimization substrate 520 allows for a greater area to accumulate particles, which improves the cleaning efficiency of the optimization substrate 520. This additional area may be exposed as the optimization substrate 520 is passed through the tool (e.g., by substrate handling robots and/or the like).

Referring now to FIG. 5C, a cross-sectional illustration of an optimization substrate 520 is shown, in accordance with yet another embodiment. In an embodiment, the optimization substrate 520 in FIG. 5C may be similar to the optimization substrate 520 in FIG. 5A, with the addition of a pattern 525 in the layer 522. The pattern 525 may comprise one or more trenches or other topography at the surface of the layer 522. In the illustrated embodiment, the pattern 525 has a plurality of uniform trenches. Though, trench dimensions (e.g., depth, width, length, slope of sidewalls, etc.) may be non-uniform across the layer 522. In an embodiment, the pattern 525 may increase the surface area of the layer 522 in order to improve attraction and capture of particles. While no second layer is shown in FIG. 5C on the first surface (i.e., bottom surface) of the substrate 521, embodiments may also comprise a second layer (patterned or unpatterned) on the first surface of the substrate 521.

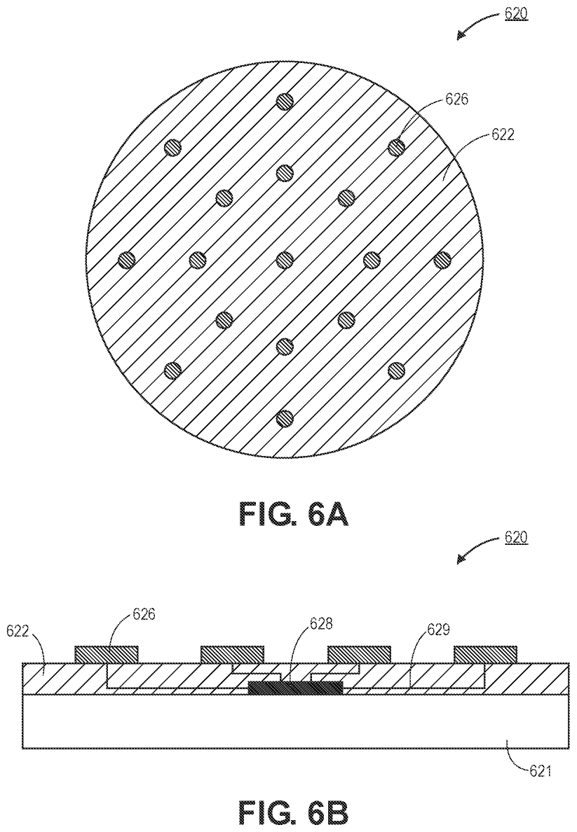

Referring now to FIGS. 6A and 6B, illustrations of portions of an optimization substrate 620 that illustrate the inclusion of one or more sensors 626 is shown, in accordance with an embodiment.

Referring now to FIG. 6A, a plan view illustration of the optimization substrate 620 is shown, in accordance with an embodiment. As shown, a layer 622 for capturing particles is provided as a top surface of the optimization substrate 620. The layer 622 may be similar to any of the layers 522 described in greater detail above. In an embodiment, one or more sensors 626 may be distributed across a surface of the optimization substrate 620. The sensors 626 may be sensors configured for providing the in-situ metrology operations with respect to process 200 described in greater detail herein. In an embodiment, the sensors 626 may be provided with any suitable layout and/or pattern across the optimization substrate 620. For example, sensors 626 may be arranged in a set of two concentric circles with an additional sensor 626 at a center of the optimization substrate 620.

In an embodiment, the sensors 626 may be sensors suitable for performing any suitable type of in-situ metrology. In a first embodiment, the sensors 626 may comprise particle sensors. For example, the sensors 626 may comprise a vibration sensor, a resonant structure sensor (e.g., a cantilever structure, or the like), or a laser light scattering sensor. Embodiments, may also comprise sensors for detecting vibrations, temperature, gas flow rates, optical stimulus (e.g., a camera, an optical emission spectroscopy (OES) system for determining plasma properties), and/or the like.

In some embodiments, the sensors 626 may also comprise one or more sensors for determining a position of the optimization substrate 620 within the tool. For example, an accelerometer (e.g., a three-axis accelerometer) may be used for position tracking. Position tracking may be beneficial since correlating a position of the optimization substrate 620 with particle detection can identify locations where particle concentrations are higher. This can inform the process where to place an optimization substrate 620 within a tool for cleaning and/or inform a decision on how long an optimization substrate 620 should remain at a certain location.

In an embodiment, a single type of sensor 626 may be provided on the optimization substrate 620. In other embodiments, two or more different types of sensors 626 may be provided on a single optimization substrate 620. In such an embodiment, the in-situ metrology process can track and/or monitor multiple different process parameters at the same time. When a single type of sensor 626 is used, multiple different optimization substrates 620 (each with different types of sensors 626) may be cycled through the tool to track and/or monitor multiple different process parameters.

Referring now to FIG. 6B, a cross-sectional illustration of a portion of an optimization substrate 620 is shown, in accordance with an embodiment. In an embodiment, the sensors 626 are provided over the surface of the layer 622. In other embodiments, the sensors 626 may be provided on the substrate 620, partially embedded in the layer 622, or provided in any suitable location. Further, while the sensors 626 are only shown as being over the top surface of the substrate 621, embodiments may also include one or more sensors 626 over the bottom surface of the substrate 621.

In an embodiment, the sensors 626 may be communicatively coupled to a controller 628. The controller 628 may be provided over the substrate 621 or at least partially embedded within the substrate 621. The sensors 626 may be communicatively coupled to the controller 628 by electrically conductive interconnects 629, such as copper traces, vias, pads, etc. In some embodiments, vias may pass through a thickness of the layer 622 and traces extend along a surface of the substrate 621 to provide the lateral connection to the controller 628.

In an embodiment, the controller 628 may provide the processing, memory, and/or power for implementing the in-situ metrology with the optimization substrate 620. For example, the controller 628 may comprise a processor, a memory, and a power source (e.g., a battery). Any suitable processor (e.g., central processing unit (CPU), application specific integrated circuit (ASIC), field programmable gate array (FPGA), etc.) may be used for the processor. Any suitable memory type may be used for the memory. The power source may be a rechargeable battery, such as a lithium ion battery, and/or the like.

In some embodiments, the data from the sensors 626 is stored on the memory within the controller 628, and the memory is accessed after the optimization substrate 620 is removed from the tool. In other embodiments, the controller 628 may further comprise a wireless communications system (e.g., Wi-Fi, Bluetooth, etc.), in order to communicate with external devices in real time, in near real time, or within any desired time period.

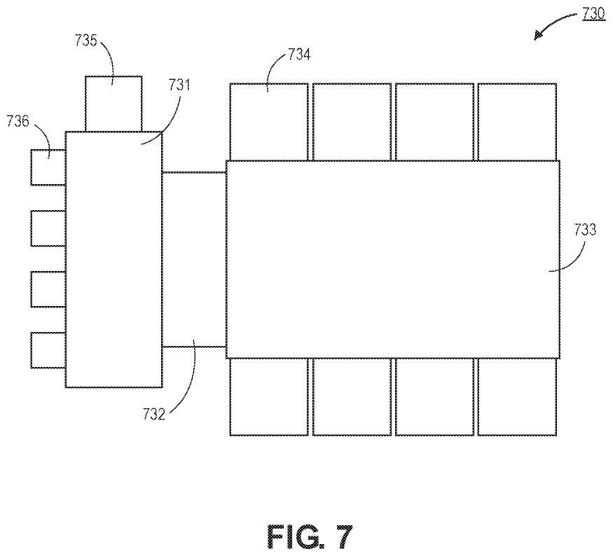

Referring now to FIG. 7, a plan view illustration of a cluster tool 730 is shown, in accordance with an embodiment. The cluster tool 730 may be a semiconductor processing tool that comprises chambers 734 for processes such as a such as, but not limited to, PVD, ALD, CVD, PEALD PECVD, etching, FEP, ECP, ion implantation, or the like. In an embodiment, the cluster tool 730 may comprise an EFEM 731. The EFEM 731 may receive front opening unified pods (FOUPs) 736 or other substrate transport devices. A wafer handling robot within the EFEM 731 transfers substrates from the FOUP 736 to a load lock 732. The load lock 732 is coupled to a transfer chamber 733 that is held at a vacuum pressure. That is, the load lock 732 allows for the transition from an atmospheric pressure environment to a vacuum environment. A substrate handling robot within the transfer chamber 733 can distribute wafers from the load lock 732 to any of the chambers 734 that are coupled to the transfer chamber 733. For example, eight chambers 734 are shown in FIG. 7. Though, one or more chambers 734 may be used in some embodiments. In an embodiment, a metrology tool 735 may be coupled to the cluster tool 730 as well. In the illustrated embodiment, the metrology tool 735 is coupled to the EFEM 731. Other embodiments may include a metrology tool 735 that is coupled to the transfer chamber 733. The metrology tool 735 may be used to provide the inline metrology described in process 200 in some embodiments.

In an embodiment, an optimization substrate (e.g., similar to any of the optimization substrates described in greater detail herein) may be provided in a FOUP 736 and transferred into the cluster tool 730 in a manner similar to any other substrate processed in the cluster tool 730. The optimization substrate may be used to clean and/or perform in-situ metrology in any of the components of the cluster tool 730. That is, the optimization substrate may clean and/or monitor one or more of the EFEM 731, the load lock 732, the transfer chamber 733, the metrology tool 735, and/or any of the chambers 734 in accordance with process 200 described in greater detail herein.

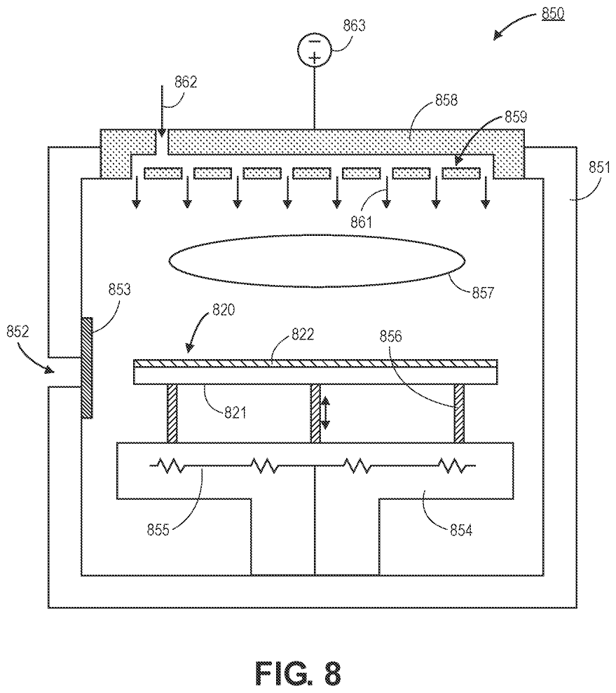

Referring now to FIG. 8, a cross-sectional illustration of a tool 850 that may be monitored and cleaned with an optimization substrate 820 is shown, in accordance with an embodiment. In an embodiment, the tool 850 may comprise a chamber 851. The chamber 851 may be suitable for supporting a vacuum pressure. For example, the vacuum pressure may be suitable to support the formation of a plasma 857 within the chamber 851. Exhaust and pumping structures are omitted for simplicity. In an embodiment, a pedestal 854 may be provided in the chamber 851 for supporting a substrate (e.g., optimization substrate 820). The substrate may be inserted into the chamber 851 through a slit valve 852 when a door 853 is opened. The substrate may be placed on lift pins 856 that can then lower (as indicated by the arrows) the substrate onto the pedestal 854. The pedestal 854 may comprise a chucking architecture (e.g., an electrostatic chuck (ESC)). The pedestal 854 may be temperature controlled as well. For example, resistive heating elements 855 may be provided in the pedestal.

In an embodiment, a lid 858 may seal the chamber 851. The lid 858 may include fluidic pathways 859 for flowing gas into 862 the lid 858 and out 861 into the chamber 851. The lid 858 may also be coupled to a power source 863 (e.g., a radio frequency (RF) power source, a microwave power source, etc.), in order to couple power into the chamber 851 to ignite and/or sustain the plasma 857.

In an embodiment, the optimization substrate 820 may comprise a substrate 821 and a layer 822. The optimization substrate 820 may also comprise sensors (not shown). In an embodiment, the optimization substrate 820 may be similar to any of the optimization substrates described in greater detail herein. In an embodiment, the optimization substrate 820 may be used in order to clean the chamber 851 and to monitor one or more different process parameter within the tool 850 through use of in-situ metrology. For example, process parameters may include one or more of gas flow rates from the lid 858, temperature of the pedestal 854, properties of the plasma 857, performance of the lift pins 856, vibrations, particle concentrations, and/or the like. While FIG. 8 provides one exemplary tool 850 configuration, it is to be appreciated that process 200 and optimization substrates 820 may be used in accordance with any tool architecture and/or type.

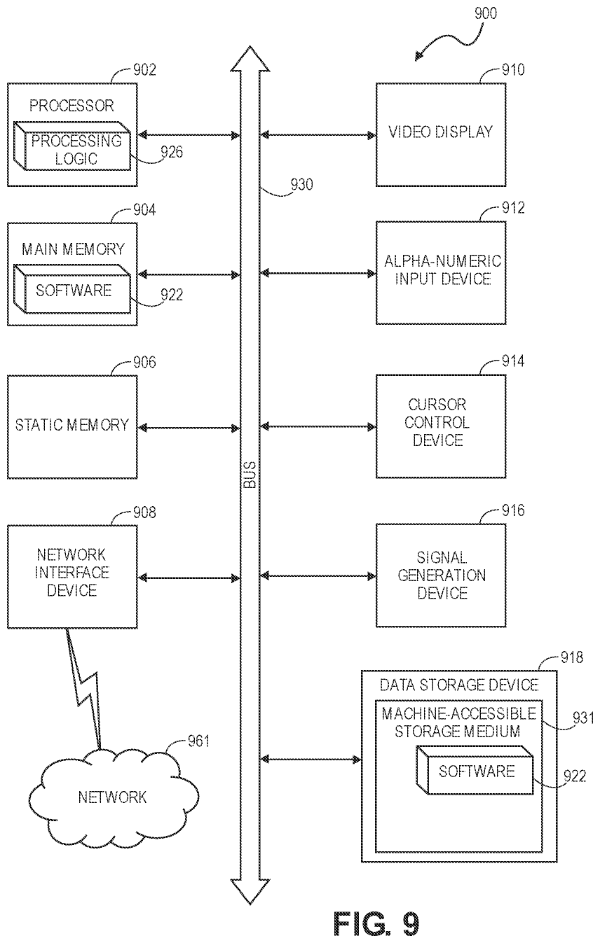

Referring now to FIG. 9, a block diagram of an exemplary computer system 900 of a processing tool is illustrated in accordance with an embodiment. In an embodiment, computer system 900 is coupled to and controls processing in the processing tool. Computer system 900 may be connected (e.g., networked) to other machines in a Local Area Network (LAN), an intranet, an extranet, or the Internet. Computer system 900 may operate in the capacity of a server or a client machine in a client-server network environment, or as a peer machine in a peer-to-peer (or distributed) network environment. Computer system 900 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 900, the term “machine” shall also be taken to include any collection of machines (e.g., computers) that individually or jointly execute a set (or multiple sets) of instructions to perform any one or more of the methodologies described herein.

Computer system 900 may include a computer program product, or software 922, having a non-transitory machine-readable medium having stored thereon instructions, which may be used to program computer system 900 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 900 includes a system processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

System processor 902 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 902 may also be one or more special-purpose processing devices such as an application specific integrated circuit (ASIC), a field programmable gate array (FPGA), a digital signal system processor (DSP), network system processor, or the like. System processor 902 is configured to execute the processing logic 926 for performing the operations described herein.

The computer system 900 may further include a system network interface device 908 for communicating with other devices or machines. The computer system 900 may also include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium 931 (or more specifically a computer-readable storage medium) on which is stored one or more sets of instructions (e.g., software 922) embodying any one or more of the methodologies or functions described herein. The software 922 may also reside, completely or at least partially, within the main memory 904 and/or within the system processor 902 during execution thereof by the computer system 900, the main memory 904 and the system processor 902 also constituting machine-readable storage media. The software 922 may further be transmitted or received over a network 961 via the system network interface device 908. In an embodiment, the network interface device 908 may operate using RF coupling, optical coupling, acoustic coupling, or inductive coupling.

While the machine-accessible storage medium 931 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for maintaining a processing tool, comprising:
performing a planned maintenance (PM) process on the processing tool;
processing substrates on the processing tool;
performing an in-situ metrology and cleaning process on the processing tool with an optimization substrate to determine if a processing parameter of the processing tool is within a specified range; and
restarting substrate processing on the processing tool when the processing parameter is within the specified range.

2. The method of claim 1, wherein the processing parameter is a particle concentration, and wherein the in-situ metrology and cleaning process comprises:
providing the optimization substrate to the processing tool, wherein the optimization substrate comprises:
a substrate;
a layer over the substrate, wherein the layer is configured to attract particles in the processing tool; and
a particle sensor on the substrate; and
processing the optimization substrate with an optimization recipe.

3. The method of claim 2, wherein the particle sensor is a vibration sensor, a resonant structure sensor, or a laser light scattering sensor.

4. The method of claim 2, wherein the optimization substrate is heated.

5. The method of claim 2, wherein the optimization substrate is charged.

6. The method of claim 2, wherein the optimization recipe is different than a process recipe used to process substrates on the processing tool.

7. The method of claim 1, wherein the in-situ metrology and cleaning process comprises cycling the optimization substrate through the processing tool a plurality of times, and wherein the cycling is continued until the processing parameter is within the specified range.

8. The method of claim 1, wherein the in-situ metrology and cleaning process is started after a predetermined duration, wherein the predetermined duration is a number of substrates that have been processed that is up to 200 substrates, or wherein the predetermined duration is a time duration that is up to one week.

9. The method of claim 1, further comprising a validation process before processing substrates on the processing tool after the PM, wherein the validation process, comprises:
performing the in-situ metrology and cleaning process with the optimization substrate; and
performing a metrology process to confirm the processing tool is processing parameter is within the specified range before processing substrates.

10. The method of claim 9, wherein the metrology process is inline metrology.

11. An apparatus, comprising:
a substrate with a first surface and a second surface opposite from the first surface;
a layer on the second surface of the substrate, wherein the layer is configured to attract particles from an environment surrounding the apparatus;
a plurality of sensors on the substrate, wherein the plurality of sensors are configured to detect particles landing on the apparatus; and
a controller on the substrate and communicatively coupled to the plurality of sensors, wherein the controller comprises:
a processor;
a memory; and
a power source.

12. The apparatus of claim 11, wherein the layer comprises a pattern, and wherein the pattern comprises one or more trenches into a surface of the layer.

13. The apparatus of claim 11, wherein the layer comprises one or more of silicon nitride, silicon oxide, aluminum, titanium, a polymer, or a sol-gel based material.

14. The apparatus of claim 11, further comprising:
a second layer on the first surface of the substrate.

15. The apparatus of claim 11, wherein the substrate comprises one or more of silicon, a ceramic, silicon carbide, graphite, or aluminum.

16. The apparatus of claim 11, wherein the substrate has a wafer form factor or a panel form factor.

17. The apparatus of claim 11, wherein the plurality of sensors comprise one or more of an accelerometer, a resonant structure, or a laser light scattering sensor.

18. A method for maintaining a processing tool, comprising:
performing a planned maintenance (PM) process on the processing tool;
processing substrates on the processing tool;
performing an in-situ metrology and cleaning process on the processing tool with an optimization substrate to determine if a processing parameter of the processing tool is within a specified range, wherein the in-situ metrology and cleaning process comprises:
providing the optimization substrate to the processing tool, wherein the optimization substrate comprises:
a substrate;
a layer over the substrate, wherein the layer is configured to attract particles in the processing tool; and
a sensor on the substrate configured to detect the processing parameter;
processing the optimization substrate with an optimization recipe a plurality of cycles until the processing parameter is within the specified range; and
restarting substrate processing on the processing tool when the processing parameter is within the specified range.

19. The method of claim 18, wherein the processing tool is a cluster tool.

20. The method of claim 18, wherein the processing parameter is one or more of a particle concentration, a vibration amount, a temperature, a gas flow, or an optical reading.
